(19) United States
(12) Patent Application Publication
(10) Pub. No.: US 2026/0050040 A1
(43) Pub. Date: Feb. 19, 2026

(54) SELF-DISCHARGE SCREENING METHOD FOR LITHIUM-ION BATTERIES, AND ELECTRONIC DEVICE

(71) Applicant: EVE POWER CO., LTD., Jingmen (CN)

(72) Inventors: Xia LI, Jingmen (CN); Zhiyong Gao, Jingmen (CN); Bin Su, Jingmen (CN); Liquan Chen, Jingmen (CN)

(73) Assignee: EVE POWER CO., LTD., Jingmen (CN)

(21) Appl. No.: 19/362,634

(22) Filed: Oct. 20, 2025

Related U.S. Application Data
(63) Continuation of application No. PCT/CN2023/137271, filed on Dec. 7, 2023.

(30) Foreign Application Priority Data
Apr. 20, 2023 (CN) 202310436085.7

(51) Int. Cl. G01R 31/378; G01R 31/36; G01R 31/374; G01R 31/385; G01R 31/388; G01R 31/392; H01M 10/44; H01M 10/48

(52) U.S. Cl. CPC G01R 31/378; G01R 31/3648; G01R 31/374; G01R 31/3865; G01R 31/388; G01R 31/392; H01M 10/441; H01M 10/488

(57) ABSTRACT

A self-discharge screening method for lithium-ion batteries is provided. In the method, a single batch screening objects includes a plurality of trays. Each tray of the plurality of trays includes a plurality of batteries to be screened. Voltage drops per unit time of the plurality of batteries to be screened are measured. Voltage drop screening thresholds of the plurality of trays are determined according to the measured voltage drops per unit time. Unqualified batteries are screened out according to a relative relationship between the voltage drop screening threshold of the tray and the voltage drops per unit time of the plurality of batteries.

### RELATED APPLICATIONS

The present application is a continuation of International application No. PCT/CN2023/137271, filed on Dec. 7, 2023, which claims priority to Chinese Patent Application No. 202310436085.7, filed on Apr. 20, 2023. The entire disclosure of the prior applications is hereby incorporated by reference.

### TECHNICAL FIELD

The present disclosure relates to battery testing technologies, including to a self-discharge screening method, a self-discharge screening apparatus for lithium-ion batteries, and an electronic device.

### BACKGROUND

In an open-circuit state, a phenomenon that electricity consumption of lithium-ion batteries occurs over time is referred to as self-discharge phenomenon of lithium-ion batteries, which is an inherent property of the lithium-ion batteries. In a lithium-ion battery system, when the self-discharge phenomenon of a battery is severe, the performance of the entire battery system will decline. Therefore, before lithium-ion batteries are released to end consumers for use, it is particularly important for manufacturers to sort out batteries with excessive self-discharge by using self-discharge screening technology.

At present, a self-discharge screening method adopted by most battery manufacturers is a fixed K value (also known as voltage drop per unit time) screening method. This screening method is easy to implement and low-cost, thereby greatly improving the factory yield of batteries.

However, in large-scale production, the fixed K value screening method shows poor measurement accuracy, affecting the factory quality of the batteries.

### SUMMARY

The present disclosure provides a self-discharge screening method for lithium-ion batteries and an electronic device, to improve the accuracy of the self-discharge screening of lithium-ion batteries.

According to a first aspect, the examples of the present disclosure provide a self-discharge screening method for lithium-ion batteries. The lithium-ion batteries include single-batch selection object that includes batteries to be screened placed in a plurality of trays. Each tray is placed with a plurality of the batteries to be screened.

The self-discharge screening method for lithium-ion batteries includes:
measuring voltage drops per unit time of the batteries to be screened;
determining voltage drop screening thresholds of the plurality of trays according to the voltage drops per unit time of the batteries to be screened in the tray; and
screening out unqualified batteries in the plurality of trays respectively according to a relative relationship between the voltage drop screening threshold of the tray and the voltage drops per unit time of the plurality of batteries to be screened in the tray

According to a second aspect, the examples of the present disclosure further provide an electronic device. The electronic device includes at least one processor and a memory coupled to the at least one processor. The memory stores a computer program executable by the at least one processor. The computer program, when executed by the at least one processor, cause the at least one processor to perform the self-discharge screening method for lithium-ion batteries according to any one of the first aspect.

### BRIEF DESCRIPTION OF THE DRAWINGS

FIG. 1 is a schematic diagram of a variation curve of a voltage of a lithium-ion battery with respect to a standing temperature according to the present disclosure;

FIG. 2 is a schematic flowchart of a self-discharge screening method for lithium-ion batteries according to examples of the present disclosure;

FIG. 3 is a schematic flowchart of another self-discharge screening method for lithium-ion batteries according to examples of the present disclosure;

FIG. 4 is a schematic flowchart of yet another self-discharge screening method for lithium-ion batteries according to examples of the present disclosure;

FIG. 5 is a schematic diagram of an SOC-V relationship curve and an SOC-dV/dQ relationship curve of a lithium iron phosphate battery according to examples of the present disclosure;

FIG. 6 is a schematic flowchart of still another self-discharge screening method for lithium-ion batteries according to examples of the present disclosure;

FIG. 7 is a schematic diagram of a variation curve of a voltage of a lithium-ion battery with respect to a standing time according to the present disclosure;

FIG. 8 is a distribution diagram of K values of batteries to be screened in some trays of a single batch screening objects according to examples of the present disclosure;

FIG. 9 is a schematic diagram of a composition of a self-discharge screening apparatus for lithium-ion batteries according to examples of the present disclosure.

FIG. 10 is a schematic diagram of a composition of an electronic device according to examples of the present disclosure.

### DETAILED DESCRIPTION

As described in the background, a self-discharge screening method adopted by most battery manufacturers is a fixed K-value screening method, where the K value is a voltage drop per unit time of a lithium-ion battery. A specific expression of a fixed K value screening method is K=ΔV/Δt, in which K is a K value, i.e. a voltage drop per unit time of a lithium-ion battery; ΔV is a voltage drop generated during a period from when an open-circuit voltage of the battery is a first open-circuit voltage OCV1 to when the open-circuit voltage of the battery is a second open-circuit voltage OCV2, and its expression is ΔV=OCV1−OCV2; Δt is a time difference between the measurement of the first open-circuit voltage OCV1 and the measurement of the second open-circuit voltage OCV2, and its expression is Δt=t_{OCV2}−t_{OCV1}, in which t_{OCV2} is the time for measuring the second open-circuit voltage OCV2, and t_{OCV1} is the time for measuring the first open-circuit voltage OCV1. A screening standard for the K value is a fixed value. If the K value of the battery is greater than this fixed value, the battery is determined to be an unqualified battery with a self-discharge rate exceeding the standard. However, in large-scale production, the fixed K value screening method shows poor measurement accuracy, affecting the factory quality of the batteries.

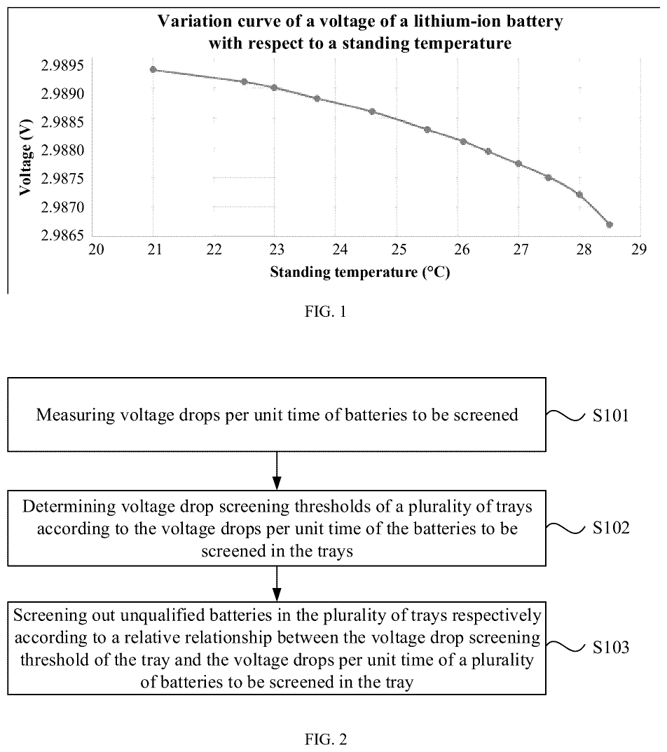

The inventors have found through research that the K value of a lithium-ion battery is affected by many factors, and may be determined by a variant of an Arrhenius equation. The variant of the Arrhenius equation is Q_{self}=Ae^{-(Ea/RT)}* t², in which Q_{self} is a capacity lost by self-discharge; Ea is an apparent activation energy, which indicates a difficulty of the self-discharge reaction, and is related to a charged state of a battery; T is a standing temperature; t is a standing time; A is a pre-exponential coefficient; R is an ideal gas constant, the value of which is 8.314J/(mol*K); Z is a power coefficient, which is generally a constant. According to the variant of the Arrhenius equation, it can be determined that the standing temperature is one of important factors affecting the K value of lithium-ion batteries. FIG. 1 is a schematic diagram of a variation curve of a voltage of a lithium-ion battery with respect to a standing temperature according to the present disclosure. Combined with FIG. 1, the inventors further studied and have found that the battery voltage is significantly affected by the standing temperature, and even for the same battery, the K values determined under different standing temperature conditions will be different. Therefore, in order to accurately screen for self-discharge, it is necessary to strictly control the temperature during the battery self-discharge test. However, in the manufacturing process of a large batch of batteries, the height of a standing warehouse is often up to ten meters, so that a plurality of batteries in the standing warehouse are often far away from each other (either horizontally or vertically). In addition, the heat generation of a plurality of batteries during the self-discharge process is also different. In this case, the cost of extreme temperature control is too high. Extreme temperature control of multiple locations in the standing warehouse is impractical for large scale manufacturing of enterprises. However, using the screening method mentioned in the background to perform self-discharge screening on lithium-ion batteries cannot consider a temperature difference among a plurality of batteries at multiple positions, which results in a poor screening effect. Therefore, how to take into account the cost and the accuracy of screening has become one of the technical challenges that lithium-ion battery manufacturers have been working hard to overcome.

Based on this, in the present disclosure, when self-discharge screening is performed on batch batteries, the trays are taken as the smallest screening units, to ensure that the standing temperatures of the batteries in each of the trays are the same, so as to eliminate interference from external environment to the maximum extent. On this basis, other technical means are combined to improve the effectiveness of self-discharge screening of batch batteries. The above is the main inventive concept of the present disclosure.

In order to solve the foregoing problems, the examples of the present disclosure provide a self-discharge screening method for lithium-ion batteries. In the self-discharge screening method for lithium-ion batteries, a single batch screening objects include batteries to be screened placed in a plurality of trays. Each tray is placed with a plurality of the batteries to be screened. FIG. 2 is a schematic flowchart of a self-discharge screening method for lithium-ion batteries provided by the examples of the present disclosure. Referring to FIG. 2, the self-discharge screening method for lithium-ion batteries includes:
Step S101, measuring voltage drops per unit time of batteries to be screened.

Specifically, a single batch screening objects include a plurality of batteries to be screened that are placed in a plurality of trays. When measuring a voltage drop (hereinafter referred to as K value for short) per unit time of the battery to be screened, differences between the open-circuit voltages of the battery to be screened before and after standing can be measured, and then the voltage drop per unit time of the battery to be screened can be calculated according to a standing duration and the difference between the open-circuit voltages. This step may be implemented by using any K value test method in relevant technologies, which will not be introduced in detail herein.
S102, determining voltage drop screening thresholds of a plurality of trays according to the voltage drops per unit time of the batteries to be screened in the trays.

Specifically, a single batch screening objects include a plurality of batteries to be screened. For example, the single batch screening objects may include thousands or tens of thousands of batteries to be screened. The plurality of batteries to be screened are separated and packed in a plurality of trays. For example, the number of batteries to be screened in one single tray may be 16 to 40. For example, the number of batteries to be screened in each tray may be equal to 16. The voltage drop screening threshold of the tray refers to a threshold that may be configured to determine whether the K values of the plurality of batteries to be screened in the tray exceed a normal range. The threshold may be an upper boundary of the normal range of the K values of the plurality of batteries to be screened in the tray. If the K value of any battery to be screened in the tray exceeds the voltage drop screening threshold of the tray, it may indicate that the self-discharge rate of the battery to be screened is unqualified. According to the K values of the plurality of batteries to be screened in the tray, an average level of the K values of the plurality of batteries to be screened in the tray may be determined. For example, the average level of the K values of the plurality of batteries to be screened in the tray may be represented by an average value or a tail-removed average value of the K values of the plurality of batteries to be screened in the tray. The voltage drop screening threshold of the tray can be determined according to the average level of the K values of the plurality of batteries to be screened in the tray. For example, the voltage drop screening threshold of the tray can be calculated by adding a preset error value on the basis of the average value of the K values of the plurality of batteries to be screened in the tray, where the preset error value can be determined according to factory requirements of the battery and a material system of the batteries to be screened.
S103, screening out unqualified batteries in the plurality of trays respectively according to a relative relationship between the voltage drop screening threshold of the tray and the voltage drops per unit time of the batteries to be screened in the tray.

Specifically, according to the voltage drop screening threshold of the tray, it is determined whether the K values of the plurality of batteries to be screened exceed a normal range. if the K value exceed the normal range, the battery to be screened is determined to be an unqualified battery; if the K value do not exceed the normal range, the battery to be screened is determined to be a qualified battery. For example, all batteries to be screened with a K value greater than a voltage drop screening threshold of a tray where the battery to be screened is located may be determined as an unqualified battery.

According to the self-discharge screening method for lithium-ion batteries provided in the examples of the present disclosure, a single batch screening objects include batteries to be screened placed in a plurality of trays. Each tray is placed with a plurality of the batteries to be screened. During a screening process, the voltage drops per unit time of a plurality of batteries to be screened are measured, and voltage drop screening thresholds of the plurality of trays are determined according to the voltage drops per unit time of the batteries to be screened in the trays. According to a relative relationship between the voltage drop screening threshold of the tray and the voltage drops per unit time of a plurality of batteries to be screened in the tray, the unqualified batteries in the plurality of trays are screened out respectively, thereby realizing self-discharge screening of the batch of lithium-ion batteries. The screening threshold of the tray is determined according to the voltage drops per unit time of the plurality of batteries to be screened in the tray, thereby avoiding the temperature influence caused by long distance among batteries to be screened during a standing process, which not only reduces the temperature control cost of the manufacturer, but also improve the accuracy of the self-discharge screening of the lithium-ion batteries.

Combined with the variant of the Arrhenius equation, it can also be determined that the charge state of the battery is also one of the important factors affecting the K value of the lithium-ion battery. Therefore, based on the foregoing examples, before measuring the voltage drops per unit time of the plurality of batteries to be screened, it is necessary to adjust the charge state of the lithium-ion batteries, to adjust the charge state of the batteries to be screened in the tray to the same value. The determination of an adjustment value of the charge state needs to be further investigated.

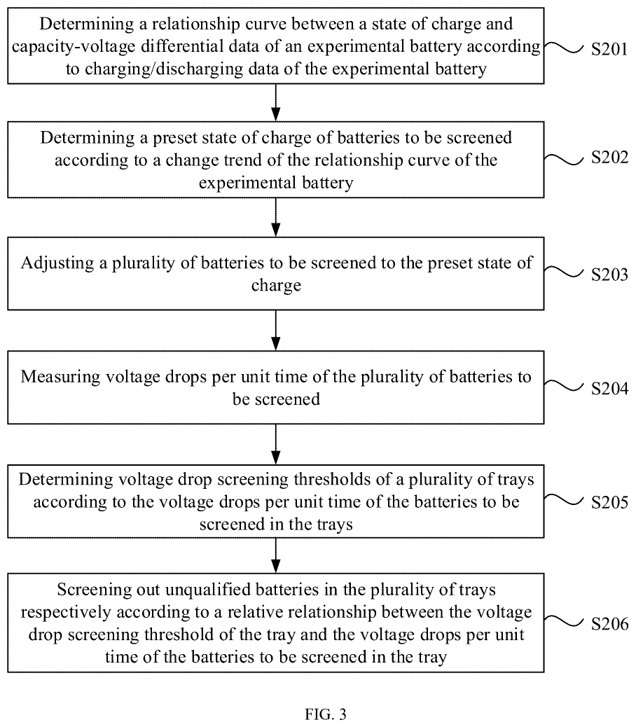

FIG. 3 is a schematic flowchart of another self-discharge screening method for lithium-ion batteries provided by the examples of the present disclosure. Referring to FIG. 3, the self-discharge screening method for lithium-ion batteries includes:
S201, determining a relationship curve between a charge state and capacity-voltage differential data of an experimental battery according to charging/discharging data of the experimental battery.

A material system of the experimental battery is the same as that of the batteries to be screened. The experimental battery refers to a battery that has the same material system as that of the battery to be screened and is configured to perform charge-discharge experiments. The same material system means that the active materials and charging and discharging principles used in the lithium-ion batteries are the same. The material system may also be referred to as a negative electrode system. For example, the material system of a lithium cobalt oxide battery is lithium cobalt oxide, and the material system of a lithium iron phosphate battery is lithium iron phosphate. The capacity-voltage differential data refers to data including a differential quantity of a capacity and a differential quantity of a voltage, and the differential quantity may be a first-order differential or a multi-order differential. For example, the capacity-voltage differential data may be a ratio dV/dQ of a differential voltage to a differential capacity.

Specifically, a small current below 0.05 C is used to perform a charge-discharge experiment on an experimental battery, and charging/discharging parameters are recorded. For example, the charging/discharging parameters may include electric quantity and voltage data. After obtaining the charging/discharging data, it is necessary to process the charging/discharging data to remove obvious erroneous data. The capacity-voltage differential data of the experimental battery is determined according to the charging/discharging data. By using the capacity-voltage differential data as a vertical coordinate and using the charge state, etc. as a horizontal coordinate, a standard relationship curve between the charge state and the capacity-voltage differential data can be obtained.

For example, a small current of 0.04 C is used to charge and discharge the experimental battery, and the electric quantity and voltage of the experimental battery during the charging and discharging process are recorded. After obtaining these data, first removing obvious erroneous data points in these data, and then subtracting voltage and electric quantity data of a previous data point from the voltage and electric quantity data corresponding to each data point, so as to obtain dV data and dQ data of a current data point. By processing all the data in sequence, a series of dV data and dQ data can be obtained, and then dQ is divided by dV to obtain a capacity-voltage differential data of the experimental battery, i.e., the ratio dV/dQ of a differential voltage to a differential capacity. Then, by using dV/dQ as a vertical coordinate and using the charge state as a horizontal coordinate, a standard relationship curve between the charge state and dV/dQ can be obtained.
S202, determining a preset charge state of batteries to be screened according to a change trend of the relationship curve of the experimental battery.

Specifically, the preset charge state may be a determined value, and may also be an interval. The relationship curve between the charge state and the capacity-voltage differential data of the experimental battery, may reflect the capacity of the lithium-ion battery of the material system in a unit voltage range under different states of charge. A change trend of the relationship curve can be reflected in a fluctuation of the capacity-voltage differential data with the change of the charge state during the charging and discharging process. If a fluctuation rate of the capacity-voltage differential data in a certain charge state interval, is larger than in other charge state intervals, it may indicate that the voltage change caused by self-discharge in this charge state interval is more significant. For example, a slope of the relationship curve may represent a rate of change in the fluctuation of the capacity-voltage differential data with respect to the charge state. Therefore, a low-charge interval and a high-charge interval in a charge state interval where an absolute value of the slope of the relationship curve is greater than a preset value can be removed to determine the preset charge state of the battery to be screened. Under the preset charge state, the voltage drop of the battery per unit time varies greatly with the unit charge state, which can reduce the impact of system errors on a screening result.
S203, adjusting a plurality of batteries to be screened to the preset charge state.

Specifically, a charging and discharging apparatus is used to perform charging or discharging operations on all batteries to be screened, so that the states of charge of the batteries to be screened are unified to a preset charge state, so as to facilitate subsequent further screening.
S204, measuring voltage drops per unit time of the plurality of batteries to be screened.
S205, determining voltage drop screening thresholds of a plurality of trays according to the voltage drops per unit time of the batteries to be screened in the trays.
S206, screening out unqualified batteries in the plurality of trays respectively according to a relative relationship between the voltage drop screening threshold of the tray and the voltage drops per unit time of the batteries to be screened in the tray.
Step S204, step S205, and step S206 are the same in detail as step S101, step S102, and step S103 in one-to-one correspondence, and details are not repeated herein.

According to the self-discharge screening method for lithium-ion batteries provided by this example, before measuring the voltage drops per unit time of a plurality of batteries to be screened, an experimental battery with the same material system as that of a current batch screening objects is used to determine the preset charge state. In this process, a relationship curve between a charge state and capacity-voltage differential data of the experimental battery is determined according to charging/discharging data of the experimental battery, and then the preset charge state of the battery to be screened is determined according to a change trend of the relationship curve of the experimental battery. The states of charge of the plurality of batteries to be screened are adjusted to the preset charge state, and then further screening is performed. Due to the different voltage drops caused by self-discharge of a fixed amount of electricity from the batteries to be screened under different states of charge, the uniform adjustment of the charge state to the preset charge state can avoid the influence of the states of charges on the K values of a plurality of batteries to be screened, and the accuracy of self-discharge screening can be further improved.

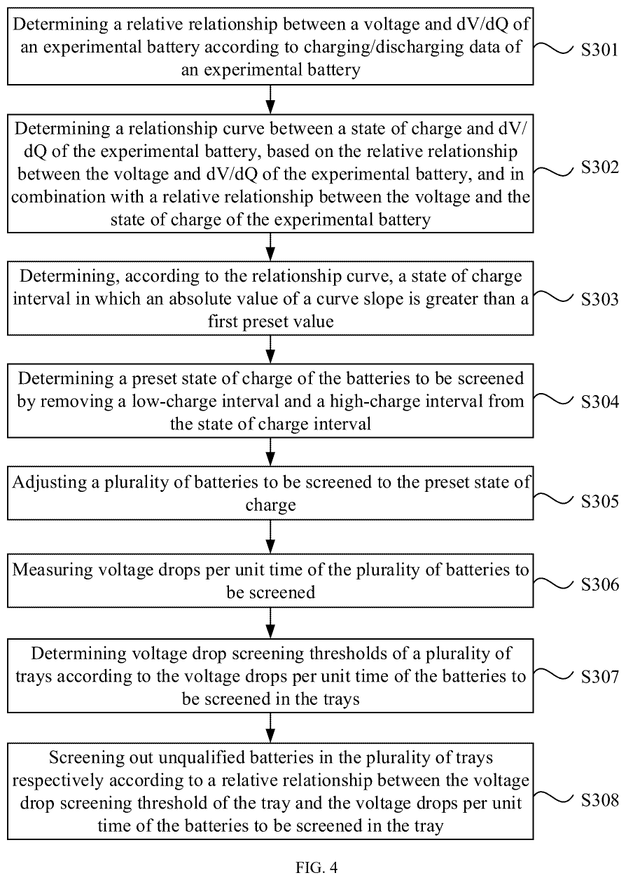

FIG. 4 is a schematic flowchart of yet another self-discharge screening method for lithium-ion batteries according to the examples of the present disclosure. Referring to FIG. 4, material systems of the experimental battery and the batteries to be screened may both be lithium iron phosphate, the capacity-voltage differential data includes a ratio dV/dQ of a differential voltage to a differential capacity. On this basis, the self-discharge screening method for lithium-ion batteries may include:
S301, determining a relative relationship between a voltage and dV/dQ of an experimental battery according to charging/discharging data of an experimental battery.

Specifically, a small current is used to perform a charge-discharge experiment on an experimental battery, where the small current may be 0.04 C. By measuring electric quantity data and voltage data during a charge-discharge experiment process, so as to determine a relative relationship between a voltage and dV/dQ of the experimental battery.

For example, a small current of 0.04 C is used to charge and discharge the experimental battery, and the electric quantity and voltage of the experimental battery during the charging and discharging process are recorded. After obtaining these data, first removing obvious erroneous data points in these data, and then subtracting voltage and electric quantity data of a previous data point from the voltage and electric quantity data corresponding to each data point, so as to obtain dV data and dQ data of a current data point. By processing all the data in sequence, a series of dV data and dQ data can be obtained, and then dQ is divided by dV to obtain a capacity-voltage differential data of the experimental battery, i.e., the ratio dV/dQ of a differential voltage to a differential capacity. Then, by using dV/dQ as a vertical coordinate and using a battery voltage corresponding to dV/dQ as a horizontal coordinate, a standard relationship curve between the voltage and dV/dQ can be obtained.
S302, determining a relationship curve between a charge state and dV/dQ of the experimental battery, based on the relative relationship between the voltage and dV/dQ of the experimental battery, and in combination with a relative relationship between the voltage and the charge state of the experimental battery.

Specifically, there is a corresponding relationship between the voltage and the charge state of the experimental battery. Based on the relative relationship between the voltage and dV/dQ of the experimental battery, in combination with the relative relationship between the voltage and the charge state of the experimental battery, the relationship curve between the charge state and dV/dQ of the experimental battery can be determined.

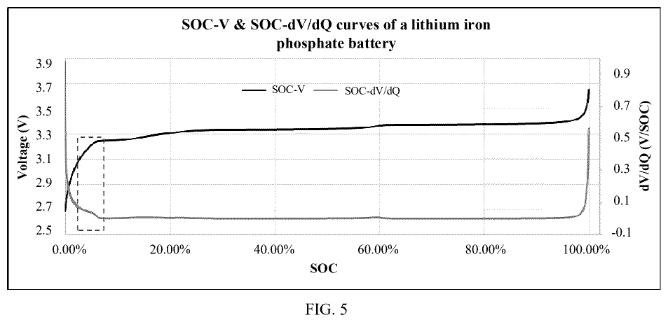

For example, FIG. 5 is a schematic diagram of an SOC-V relationship curve and an SOC-dV/dQ relationship curve of a lithium iron phosphate battery according to the examples of the present disclosure. Combined with FIG. 5, the capacity-voltage differential data of the lithium iron phosphate battery may be a ratio of a differential voltage to a differential electricity quantity. The curve SOC-V shows a relationship curve between the charge state and the voltage of the lithium iron phosphate battery determined according to the small-current charge-discharge experiment. The curve SOC-dV/dQ shows a relationship curve between the charge state and the capacity-voltage differential data of the lithium iron phosphate battery determined according to the small-current charge-discharge experiment. It can be obtained from the slopes of the curves SOC-V and SOC-dV/dQ that, when the charge state is in a range of 4.5-98%, the differential data of the voltage and the capacity-voltage of the lithium iron phosphate battery changes slowly with charging and discharging. In contrast, when the charge state is in a range of 0-4.5% or 98-100%, the differential data of the voltage and the capacity voltage of the lithium iron phosphate battery changes quickly with charging and discharging.
S303, determining, according to the relationship curve, a charge state interval in which an absolute value of a curve slope is greater than a first preset value.

Specifically, according to the relationship curve between the charge state and the capacity-voltage differential data of the experimental battery, a change in the slope of the curve may be determined. The absolute value of the slope may indicate the rate of change of the capacity-voltage differential data with respect to the charge state. The larger the absolute value of the slope is, the faster the capacity-voltage differential data changes with respect to the charge state. With the change of the electric quantity, the battery voltage also changes significantly, and it is more convenient to measure the voltage drop caused by self-discharge during the standing process. Therefore, by determining the preset charge state within the charge state interval in which the absolute value of the slope of the curve is greater than the first preset value, the system error can be reduced. For example, the first preset value may be equal to 0.05.
S304, determining a preset charge state of the batteries to be screened by removing a low-charge interval and a high-charge interval from the charge state interval.

Specifically, the low-charge interval refers to a charge state interval in which the charge state is approximately 0%. The inventors have found through research that if the battery to be screened is adjusted to the low-charge interval and then the voltage drop per unit time is measured, the self-discharge during the standing state may easily cause the battery to be screened to reach an electric quantity of 0 before the standing is completed, resulting in inaccurate measurement of voltage drop per unit time. Therefore, the charge state in the low-charge interval is not suitable as the preset charge state. For example, the low-charge interval may include a charge state between 0 and 0.5%.

The high-charge interval refers to a charge state interval in which the charge state is approximately 100%. The inventors have found through research that if the battery to be screened is adjusted to the high-charge interval and then the voltage drop per unit time is measured, considering that the large number of a single batch of batteries to be screened, a safety risk of self-discharge during standing is high, and therefore, the charge state in the high-charge interval is also not suitable as the preset charge state. For example, the high-charge interval may include a charge state of 60% to a charge state of 100%. By removing the low-charge interval and the high-charge interval from the charge state interval, the preset charge state of the battery to be screened can be determined.

For example, continuing to refer to FIG. 5, according to the relationship curve between the charge state and capacity-voltage differential data of the lithium iron phosphate battery, it may be determined that the charge state intervals in which the absolute value of the slope of the curve is greater than 0.05 are 0%-4.5% and 98%-100%. The low-charge interval 0-0.5% and the high-charge interval 98-100% are removed from the charge state interval, and it can be obtained that the preset charge state of the lithium iron phosphate battery is 0.5-4.5%, which is shown in a dotted box.
S305, adjusting a plurality of batteries to be screened to the preset charge state.
S306, measuring voltage drops per unit time of the plurality of batteries to be screened.
S307, determining voltage drop screening thresholds of a plurality of trays according to the voltage drops per unit time of the batteries to be screened in the trays.
S308, screening out unqualified batteries in the plurality of trays respectively according to a relative relationship between the voltage drop screening threshold of the tray and the voltage drops per unit time of the batteries to be screened in the tray.
Steps S305-S308 are the same in detail as the aforementioned steps S203-S206 in one-to-one correspondence, and details are not repeated herein.

According to the self-discharge screening method for lithium-ion batteries provided by this example, before measuring the voltage drops per unit time of the plurality of batteries to be screened, the relative relationship between the voltage and dV/dQ of an experimental battery is determined according to the charging/discharging data of the experimental battery. Bases on the relative relationship between the voltage and dV/dQ of the experimental battery, combined with the relative relationship between the voltage and the charge state of the experimental battery, the relationship curve between the charge state and capacity-voltage differential data of the experimental battery is determined. The preset charge state is determined according to the slope of the relationship curve, thereby realizing the determination and unification of the charge state of the batteries to be screened. Under the preset charge state, the voltage drops of the batteries to be screened during a self-discharge process is significant, thereby reducing the influence of system errors on the screening accuracy.

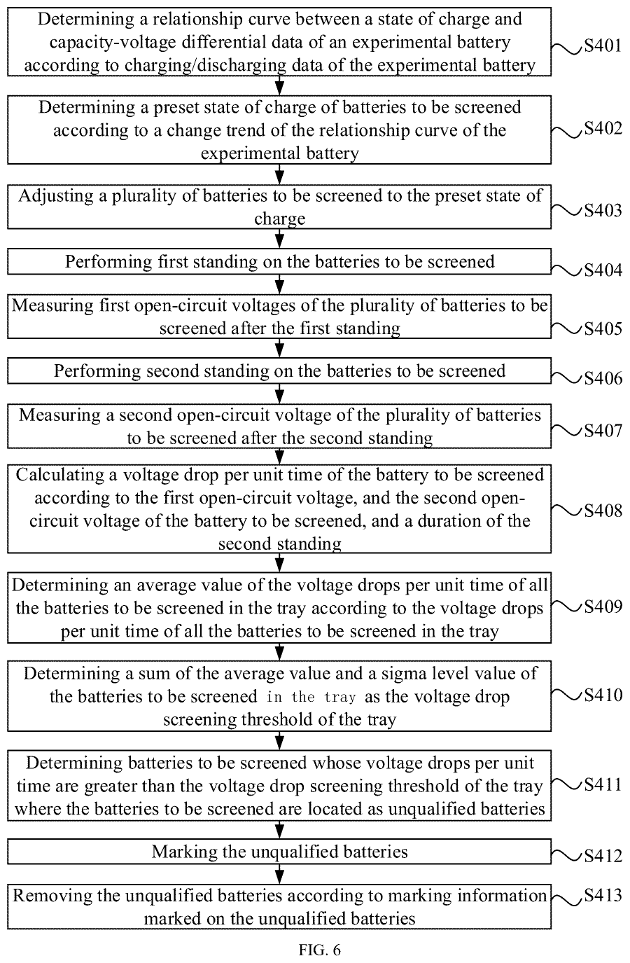

FIG. 6 is a schematic flowchart of still another self-discharge screening method for lithium-ion batteries provided by the examples of the present disclosure. With reference to FIG. 6, the self-discharge screening method for lithium-ion batteries includes:
S401, determining a relationship curve between a charge state and capacity-voltage differential data of an experimental battery according to charging/discharging data of the experimental battery.
S402, determining, according to a change trend of the relationship curve of the experimental battery, a preset charge state of batteries to be screened.

S403, adjusting a plurality of batteries to be screened to the preset charge state.
Steps S401-S403 are the same in detail as the aforementioned steps S201-S203 in one-to-one correspondence, and details are not repeated herein.
S404, performing first standing on the batteries to be screened.

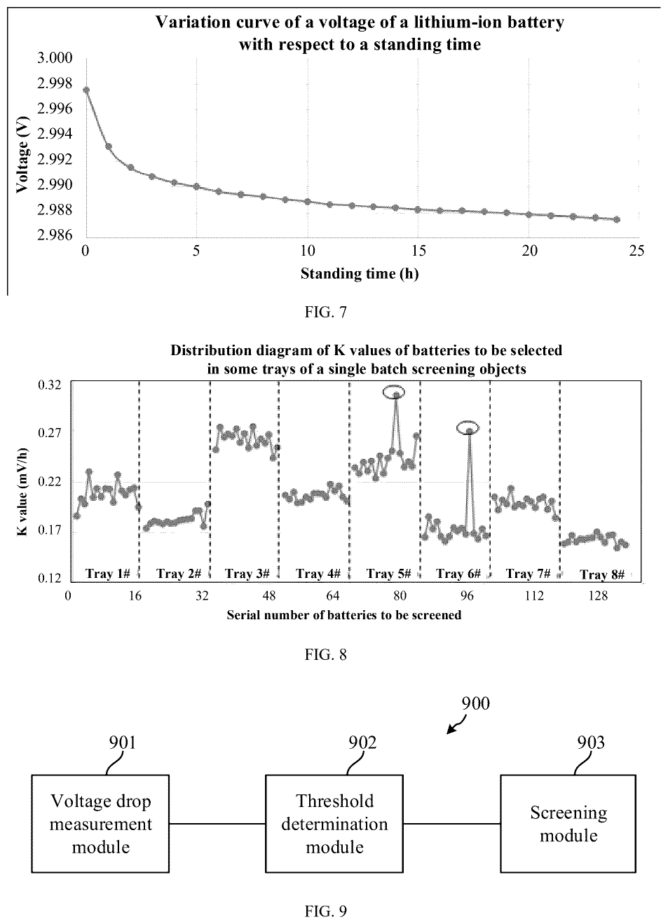

Specifically, FIG. 7 is a schematic diagram of a curve showing a voltage change of a lithium-ion battery with respect to a standing time according to the present disclosure. With reference to FIG. 7, for a battery that has just undergone charging and discharging, the voltage drops rapidly in the early stage of standing, and then the drop rate tends to stabilize. However, the time intervals of different batteries to be screened from a previous charging/discharging to the current time may be different. Therefore, if the voltage before and after standing is directly measured and the K value of the battery to be screened is calculated according to the voltage before and after standing and a standing duration, the K value obtained will have a larger error compared with an actual value. Therefore, in the examples of the present disclosure, the first standing is first performed on a plurality of batteries to be screened that are under a preset charge state, so that the self-discharge speed tends to a stable value, eliminating the influence of polarization on the self-discharge speed of the batteries. Conditions of the first standing include time conditions and temperature conditions. For example, the temperature of the first standing may be equivalent to the temperature of an application condition of the batteries to be screened, the duration of the first standing can be set according to the time from the completion of charging and discharging to the time when the voltage reduction rate tends to stabilize in the experiment. The temperature of the first standing may be any value from 20° C. to 30° C., and the duration of the first standing may be any value from 8 hours to 16 hours. For example, the temperature of the first standing may be 25° C. and the duration may be 10 hours.
S405, measuring first open-circuit voltages of the plurality of batteries to be screened after the first standing.

Specifically, the first standing may eliminate the influence of polarization phenomena on the battery voltage. After the first standing, the rate of decrease of the battery voltage will remain stable, and at this time, the open-circuit voltage of the battery to be screened is measured as the first open-circuit voltage.
S406, performing second standing on the batteries to be screened.

Specifically, the standing temperature of the second standing is consistent with that of the first standing. In order to make the self-discharge voltage drop in the second standing more obvious and reduce the influence of the system errors on the calculation result, the standing duration of the second standing may be longer than that of the first standing. For example, the duration of the second standing may be any value between 60 hours to 90 hours. For example, the duration of the second standing may be 70 hours, and the temperature of the second standing is the same as that of the first standing, which may be 25° C.
S407, measuring a second open-circuit voltage of the plurality of batteries to be screened after the second standing.

Specifically, during the second standing, the plurality of batteries to be screened all generate a certain voltage drop due to self-discharge. After the second standing is completed, the voltage of the batteries to be screened may be measured as the second open-circuit voltage of the batteries to be screened.
S408, calculating a voltage drop per unit time of the battery to be screened according to the first open-circuit voltage and the second open-circuit voltage of the battery to be screened, and a duration of the second standing.

Specifically, a difference between the first open-circuit voltage and the second open-circuit voltage may be regarded as the voltage drop caused by self-discharge during the second standing. In addition, by dividing the duration of the second standing by the voltage drop caused by self-discharge during the second standing, the voltage drops per unit time of the battery to be screened can be obtained. The same as a specific expression of the foregoing fixed K value screening method, a formula for calculating a voltage drop per unit time of a battery to be screened may be K value=(OCV1−OCV2)/t, in which the K value is a voltage drop per unit time of the battery to be screened, OCV1 is a first open-circuit voltage, OCV2 is a second open-circuit voltage, and t is a duration of the second standing. According to this formula, voltage drops per unit time of all the batteries to be screened in a single batch screening are calculated.

For example, FIG. 8 is a distribution diagram of K values of batteries to be screened in some trays of a single batch of objects to be screened provided in the examples of the present disclosure. With reference to FIG. 8, thousands of batteries to be screened are included in the single batch of objects to be screened. Under this large-scale production manner, the consistency of the K values of the batteries to be screened in a single tray is better, while the consistency of the K values of the batteries to be screened in different trays is poor. The reason is that a vertical height of a standing warehouse is generally more than 10 meters, during the second standing, each of the batteries to be screened is located in a different position in the standing warehouse. The differences in the position distribution of a plurality of trays in the standing warehouse and the self-discharge heat generation of some batteries causes differences in the ambient temperature of each tray. For a plurality of batteries to be screened in the same tray, their vertical distance is 0 and the horizontal distance is small, and the difference between the K values is small, so that it is easier to determine batteries with abnormal self-discharge in a single tray according to the K values.
S409, determining an average value of the voltage drops per unit time of all the batteries to be screened in the tray according to the voltage drops per unit time of all the batteries to be screened in the tray.

Specifically, according to the voltage drop per unit time of all the batteries to be screened in the tray, an average value of the voltage drops per unit time of the batteries to be screened in the tray may be determined. For example, the average value may be an arithmetic average value, which is calculated by dividing the number of the batteries to be screened in the tray by a sum of the voltage drops per unit time of all the batteries to be screened in the tray. The calculation formula is expressed as: K̅=(K₁+K₂+ . . . . Kₙ)/n, in which K̅ is an average value of voltage drops per unit time of the batteries to be screened in the tray, Kₙ is a voltage drop per unit time of the nth battery to be screened in the tray, and n is the number of batteries to be measured in the tray. The average value may also be a tail-removed average value, which may be calculated by removing the batteries to be screened having the maximum voltage drop and the minimum voltage drop per unit time in the tray, and dividing the total number of the remaining batteries to be screened by the sum of the voltage drops per unit time of the remaining batteries to be screened. In this manner, calculation of the average values corresponding to all trays in a single batch screening is completed.
S410, determining a sum of the average value and a sigma level value of the batteries to be screened in the tray as the voltage drop screening threshold of the tray.

Specifically, when determining the voltage drop screening threshold of the tray, the tray is taken as a unit, and a corresponding voltage drop screening threshold is calculated for each tray according to an average value of the voltage drops per unit time of the batteries to be screened in the tray. The voltage drop screening threshold is taken as a voltage drop judgement threshold for a plurality of batteries to be screened in a corresponding tray, and is configured to judge whether the voltage drops per unit time of the plurality of batteries to be screened are normal. The sigma level value is a product of a standard deviation and a weight constant, where the standard deviation refers to a standard deviation of the voltage drops per unit time of all the batteries to be screened in a tray where the batteries to be screened are located, and is expressed by a calculation formula:

$$σ = \sqrt{\sum [ {( {K}_{1} - \overline{K} )}^{2} + {( {K}_{2} - \overline{K} )}^{2} + {( {K}_{2} - \overline{K} )}^{2} ] / n} ,$$

in which σ is a standard deviation. The value of the weight constant is respectively related to an initial set value and experimental data of battery disassembly, where the value of the weight constant in an initial batch screening is equal to the initial set value. For example, the initial set value is any value between 2 and 3. The experimental data of battery disassembly is experimental data obtained by disassembling the unqualified batteries in historical screenings. Before the disassembling experiment, it is necessary to store the unqualified batteries to be disassembled for a long period of time, and it is determined in the disassembling experiment whether the unqualified batteries have short circuit points, so as to record and generate the battery disassembly experiment data. For example, a long-term storage time may be greater than 30 days.

For example, the initial set value may be set to 2. If the factory needs are strict, the initial set value may be set to a smaller value. If the factory needs are loose, the initial set value may be set to a larger value. The smaller the weight constant is, the more unqualified batteries are screened out, and the higher the effectiveness of screening is. However, some of the unqualified batteries screened out may be good products. Therefore, the value of the weight constant in the initial batch screening may be equal to the initial set value, so as to determine a first batch of unqualified batteries, and the unqualified batteries screened out can be further disassembled using a battery disassembly experiment, so as to confirm whether the unqualified batteries screened out for the first time have short-circuit points. The effectiveness of the previous screening is determined according to the experimental data of the disassembly experiments, thereby further correcting the weight constant. In subsequent screening, a corrected weight constant may be used for screening. If the weight constant needs to be further corrected, a disassembly experiment may be performed again on the unqualified batteries screened out last time. The voltage drop screening thresholds of all the trays are determined respectively using the above manner.
S411, determining batteries to be screened whose voltage drops per unit time are greater than the voltage drop screening threshold of the tray where the batteries to be screened are located as unqualified batteries.

Specifically, it is determined, according to whether the voltage drops per unit time of the plurality of batteries to be screened are greater than the voltage drop screening threshold corresponding to the tray where the batteries to be screened are located, whether the batteries to be screened are unqualified batteries. The batteries to be screened whose voltage drops per unit time are greater than the voltage drop screening threshold of the tray where the batteries to be screened are located are determined as unqualified batteries. Referring to FIG. 8, the batteries enclosed in tray 5 and tray 6 are unqualified batteries.
S412, marking the unqualified batteries.

Specifically, the unqualified batteries are marked according to the determination result of step S411. The marking manner may be setting marking information on the surface of the unqualified batteries, or adding marking information before or after archived serial numbers of the unqualified batteries.
S413, removing the unqualified batteries according to marking information marked on the unqualified batteries.

Specifically, the unqualified batteries with marking information are removed from the batteries to be screened. For example, a surface image of the battery to be screened can be identified by using an image recognition technology, so as to determine an unqualified battery with marking information on its surface, and a mechanical arm is used to pick up the unqualified battery from the batteries to be screened. It is also possible to query the target placement location corresponding to the unqualified battery with marking information in the archive number, and then use the robotic arm to pick up the unqualified battery at the target placement location

According to the self-discharge screening method for lithium-ion batteries provided by this example, before measuring the voltage drops per unit time of a plurality of batteries to be screened, an experimental battery with the same material system as that of a current batch screening objects is used to determine a preset charge state. In this process, a relationship curve between a charge state and capacity-voltage differential data of the experimental battery is determined according to charging/discharging data of the experimental battery, and then the preset charge state of the battery to be screened is determined according to a change trend of the relationship curve of the experimental battery. The states of charge of the plurality of batteries to be screened are adjusted to the preset charge state, and then further screening is performed. Due to the different voltage drops caused by self-discharge of a fixed amount of electricity from the batteries to be screened under different states of charge, the uniform adjustment of the charge state to the preset charge state can avoid the influence of the states of charges on the K values of a plurality of batteries to be screened, and the accuracy of self-discharge screening can be further improved.

The examples of the present disclosure further provide a self-discharge screening apparatus for lithium-ion batteries. FIG. 9 is a schematic diagram of a composition of a self-discharge screening apparatus for lithium-ion batteries provided by the examples of the present disclosure. With reference to FIG. 9, the self-discharge screening apparatus 900 for lithium-ion batteries includes: a voltage drops measurement module 901, a threshold determination module 902, and a screening module 903. The voltage drops measurement module 901 is configured to measure voltage drops per unit time of a plurality of batteries to be screened. The threshold determination module 902 is configured to determine voltage drop screening thresholds of a plurality of trays according to the voltage drops per unit time of the batteries to be screened in the trays. The selection module 903 is configured to screen out unqualified batteries in the plurality of trays respectively according to a relative relationship between a voltage drop screening threshold of the tray and the voltage drops per unit time of a plurality of batteries to be screened in the tray.

The above-mentioned self-discharge screening apparatus 900 for lithium-ion batteries can execute the self-discharge screening method for lithium-ion batteries provided by any example of the present disclosure, and has corresponding functional modules 901-903 for executing the self-discharge screening method for lithium-ion batteries, and can bring corresponding beneficial effects as mentioned in the above method examples of the present disclosure. The specific technical details of operations performed by the functional modules and beneficial effects achieved can be referred to the detailed description of the previous method examples, which will not be repeated here.

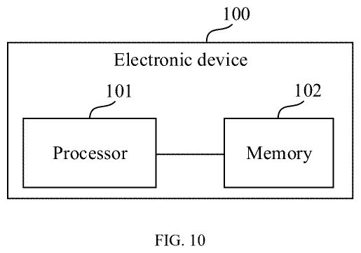

Referring to FIG. 10, the examples of the present disclosure further provide an electronic device 100. The electronic device 100 includes processing circuitry, such as at least one processor 101, and a memory 102 communicatively coupled to the at least one processor 101. The memory 102 stores a computer program executable by the at least one processor 101. The computer program is executed by the at least one processor 101, so that the at least one processor 101 can execute the self-discharge screening method for lithium-ion batteries in any of the above method examples of the present disclosure, and can bring corresponding beneficial effects as mentioned in the above method examples of the present disclosure.

What is claimed is:

1. A self-discharge screening method for lithium-ion batteries comprising:
a single batch screening objects including a plurality of trays, each tray of the plurality of trays comprising a plurality of batteries to be screened; measuring, by processing circuitry, a voltage drop per unit time of each of the plurality of batteries;
determining, by the processing circuitry, a voltage drop screening threshold of each of the plurality of trays according to a measured voltage drop; and
screening out, by the processing circuitry, unqualified batteries from each tray of the plurality of trays respectively according to a relative relationship between the voltage drop screening threshold and a corresponding voltage drop per unit time of each of the plurality of batteries in each of the plurality of trays.

2. The self-discharge screening method for lithium-ion batteries according to claim 1, wherein before measuring the voltage drop per unit time of each of the plurality of batteries, the method further comprises:
determining a relationship curve between a charge state and capacity-voltage differential data of an experimental battery according to charging/discharging data of the experimental battery, a material system of the experimental battery being a same as each of the plurality of batteries to be screened;
determining a preset charge state of each of the plurality of batteries to be screened according to a change trend of the relationship curve of the experimental battery; and
adjusting each of the plurality of batteries to be screened to the preset charge state.

3. The self-discharge screening method for lithium-ion batteries according to claim 2, wherein
the material systems of the experimental battery and each of the plurality of batteries to be screened are both lithium iron phosphate;
the capacity-voltage differential data comprises a ratio, denoted as dV/dQ, of a differential voltage to a differential capacity;
the determining the relationship curve between the charge state and capacity-voltage differential data of the experimental battery according to the charging/discharging data of the experimental battery further comprises:
determining a relative relationship between a voltage and dV/dQ of the experimental battery according to the charging/discharging data of the experimental battery; and
determining a relationship curve between the charge state and dV/dQ of the experimental battery, based on the relative relationship between the voltage and dV/dQ of the experimental battery, and in combination with a relative relationship between the voltage and the charge state of the experimental battery.

4. The self-discharge screening method for lithium-ion batteries according to claim 2, wherein the determining the preset charge state further comprises:
determining charge state intervals in which each absolute value of a curve slope of the relationship curve is greater than a first preset value; and
determining the preset charge state of the batteries to be screened by removing a low-charge interval and a high-charge interval from the charge state intervals.

5. The self-discharge screening method for lithium-ion batteries according to claim 3, wherein the determining the preset charge state further comprises:
determining charge state intervals in which each absolute value of a curve slope of the relationship curve is greater than a first preset value; and
determining the preset charge state of the batteries to be screened by removing a low-charge interval and a high-charge interval from the charge state intervals.

6. The self-discharge screening method for lithium-ion batteries according to claim 1, wherein the measuring the voltage drop further comprises:
performing first standing on each of the plurality of batteries to be screened;
measuring a first open-circuit voltage of each of the plurality of batteries after the first standing;
performing second standing on each of the plurality of batteries, a standing temperature of the second standing being consistent with the first standing;
measuring a second open-circuit voltage of each of the plurality of batteries after the second standing; and
calculating the voltage drop per unit time of each of the plurality of batteries according to the first open-circuit voltage and the second open-circuit voltage, and a duration of the second standing.

7. The self-discharge screening method for lithium-ion batteries according to claim 2, wherein the measuring the voltage drop further comprises:
performing first standing on each of the plurality of batteries to be screened;
measuring first a first open-circuit voltage of each of the plurality of batteries after the first standing;
performing second standing on each of the plurality of batteries, a standing temperature of the second standing being consistent with the first standing;
measuring a second open-circuit voltage of each of the plurality of batteries after the second standing; and
calculating the voltage drop per unit time of each of the plurality of batteries according to the first open-circuit voltage, the second open-circuit voltage, and a duration of the second standing.

8. The self-discharge screening method for lithium-ion batteries according to claim 1, wherein the determining the voltage drop screening threshold further comprises:
determining an average value of the voltage drops per unit time of the plurality of batteries in each tray according to the voltage drops per unit time of all of the plurality of the batteries to be screened in each tray;
determining a sum of the average value and a sigma level value of the plurality of batteries to be screened in each tray as the voltage drop screening threshold of the tray; and
repeating steps of determining the average value of the voltage drops per unit time of all of the plurality of the batteries to be screened in the tray and determining the voltage drop screening threshold of each tray to complete determinations of the voltage drop screening thresholds for all of the trays in the single batch screening objects.

9. The self-discharge screening method for lithium-ion batteries according to claim 8, wherein
the sigma level value is equal to a product of a weight constant and a standard deviation;
the weight constant is respectively related to an initial set value and experimental data of battery disassembly; and
the standard deviation refers to a standard deviation of the voltage drops per unit time of all the batteries to be screened in a tray.

10. The self-discharge screening method for lithium-ion batteries according to claim 1, wherein the screening out unqualified batteries further comprises:
determining the plurality of the batteries to be screened with voltage drop per unit time are greater than the voltage drop screening threshold of the tray as the unqualified batteries;
marking the unqualified batteries with marking information; and
removing the unqualified batteries according to the marking information.

11. The self-discharge screening method for lithium-ion batteries according to claim 2, wherein the screening out unqualified batteries further comprises:
determining the plurality of the batteries to be screened with voltage drops per unit time are greater than the voltage drop screening threshold of the tray as the unqualified batteries;
marking the unqualified batteries with marking information; and
removing the unqualified batteries according to the marking information.

12. An electronic device comprising:
processing circuitry configured to:
measure voltage drops per unit time of a plurality of batteries to be screened, the plurality of batteries being a single batch to be screened and being placed in a plurality of trays, wherein each tray of the plurality of trays being placed with the plurality of the batteries;
determine voltage drop screening thresholds of the plurality of trays according to the voltage drops per unit time of the plurality of batteries; and
screen out unqualified batteries in the plurality of trays respectively according to a relative relationship between the voltage drop screening threshold of the tray and the voltage drops per unit time of the plurality of batteries.

13. The electronic device according to claim 12, wherein the processing circuitry is further configured to:
determine a relationship curve between a charge state and capacity-voltage differential data of an experimental battery according to charging/discharging data of the experimental battery;
wherein a material system of the experimental battery is the same as the plurality of batteries to be screened;
determine a preset charge state of the plurality of batteries to be screened according to a change trend of the relationship curve of the experimental battery; and
adjust the batteries to be screened to the preset charge state.

14. The electronic device according to claim 13, wherein
the material system of the experimental battery and the plurality of batteries to be screened are both lithium iron phosphate;
the capacity-voltage differential data comprises a ratio dV/dQ of a differential voltage to a differential capacity; and
the processing circuitry is further configured to
determine charge state, a relative relationship between a voltage and dV/dQ of the experimental battery according to the charging/discharging data of the experimental battery; and
determine a relationship curve between the charge state and dV/dQ of the experimental battery, based on the relative relationship between the voltage and dV/dQ of the experimental battery, and in combination with a relative relationship between the voltage and the charge state of the experimental battery.

15. The electronic device according to claim 13, wherein the processing circuitry is further configured charge state to:
determine a charge state interval in which an absolute value of a curve slope of the relationship curve is greater than a first preset value; and
determine the preset charge state of the batteries to be screened by removing a low-charge interval and a high-charge interval from the charge state interval.

16. The electronic device according to claim 14, wherein the processing circuitry is further configured charge state to:
determine a charge state interval in which an absolute value of a curve slope of the relationship curve is greater than a first preset value; and
determine the preset charge state of the batteries to be screened by removing a low-charge interval and a high-charge interval from the charge state interval.

17. The electronic device according to claim 12, wherein the processing circuitry is further configured to:
perform first standing on the plurality of batteries to be screened;
measure first open-circuit voltages of the plurality of batteries after the first standing;
perform second standing on the plurality of batteries to be screened, wherein a standing temperature of the second standing is consistent with the first standing;
measure second open-circuit voltages of the plurality of batteries after the second standing; and
calculate a voltage drop per unit time of the plurality of batteries according to the first open-circuit voltages and the second open-circuit voltages, and a duration of the second standing.

18. The electronic device according to claim 12, wherein the processing circuitry is further configured to:
determine an average value of the voltage drops per unit time of the plurality of batteries in the tray according to the voltage drops per unit time of all the batteries to be screened in the tray;
determine a sum of the average value and a sigma level value of the batteries to be screened in the tray as the voltage drop screening threshold of the tray; and
repeat two steps of determining the average value of the voltage drops per unit time of all the batteries to be screened in the tray and determining the voltage drop screening threshold of the tray to complete determinations of the voltage drop screening thresholds for all of the trays in the single batch screening objects.

19. The electronic device according to claim 18, wherein
the sigma level value is equal to a product of a weight constant and a standard deviation;
the weight constant is respectively related to an initial set value and experimental data of battery disassembly; and
the standard deviation refers to a standard deviation of the voltage drops per unit time of all the batteries to be screened in a tray.

20. The electronic device according to claim 12, wherein the processing circuitry is further configured to:
determine batteries to be screened with voltage drops per unit time are greater than the voltage drop screening threshold of the tray as the unqualified batteries;
mark the unqualified batteries with marking information; and
remove the unqualified batteries according to the marking information.
